(19) United States
(12) Patent Application Publication
(10) Pub. No.: US 2004/0232977 A1
(43) Pub. Date: Nov. 25, 2004

(54) Filter circuit

(76) Inventors: Chao-Cheng Lee, HsinChu (TW); Jui-Cheng Huang, Hsinchu City (TW); Jui-Yuan Tsai, Tainan City (TW); Wen-Chi Wang, Siluo Township (TW)

Correspondence Address: RABIN & Berdo, PC, 1101 14TH STREET, NW, SUITE 500, WASHINGTON, DC, 20005, US

(21) Appl. No.: 10/748,668

(22) Filed: Dec. 31, 2003

(30) Foreign Application Priority Data
Jan. 10, 2003 (TW) 92100494

(51) Int. Cl. H03B 1/00

(52) U.S. Cl. 327/552

(57) ABSTRACT

A filter circuit of the present invention provides a transconductance device for outputting a current signal according to an input voltage and a feedback voltage; a transresistance device coupled to the transconductance device for outputting a output voltage according to the current signal; and a feedback device coupled between the transconductance device and the transresistance device for outputting the feedback voltage according to the output voltage. The transresistance device is coupled to the transconductance device via a resistor network comprising a plurality of stages connected serially, wherein each stage of the resistor network comprises: an input node; an output node; a first resistor coupled between the input node and the ground; and a second resistor coupled between the input node and the output node.

### CROSS REFERENCE TO RELATED APPLICATIONS

The present application is related in its subject matter to that of the applicants' copending U.S. patent application entitled AMPLIFIER CIRCUIT, filed concurrently herewith on Dec. 31, 2003, which is commonly owned by the assignee of the present application, and the disclosure of which is hereby incorporated by reference. The present application also incorporates by reference the disclosure of applicants' prior corresponding Taiwan Application No. 92100495, which was filed Jan. 10, 2003, the foreign priority benefit of which is claimed herein.

### BACKGROUND OF THE INVENTION

The present invention relates in general to a filter circuit. In particular, the present invention relates to a low-pass filter circuit with variable low cut-off frequency.

Description of the Related Art

Filters are common elements in communication systems. Filters adjust the waveform of signal, suppress harmonic interference, and decrease the noise in the communication system. Recently, smaller size and higher quality filters are required in mobile communication systems.

FIG. 1 is a circuit showing the conventional low-pass filter. In FIG. 1, the cut-off frequency is

$$\frac{1}{R1 \cdot C1} .$$

When the cut-off frequency is set as 10 Hz, the product of the resistance of the resistor R1 and the capacitance of the capacitor C1 must be

$$\frac{1}{2 \cdot π \cdot 10} .$$

A reasonable capacitance of a capacitor made by common semiconductor process, however, is 10 Pf. Thus, when the capacitance of a capacitor C1 is 10 Pf, the resistance of the resistor R1 must be 1592 Meg. It is costly, however, to fabricate a resistor with resistance of 1592 Meg, which is an unreasonable value. The area requirement of the common semiconductor process to form a resistor with the resistance of 1592 Meg must be 1262 u-1262 um², which is unreasonable large to the modern IC circuit device. Thus, it is difficult to form a resistor having a very large resistance. Thus, the cut-off frequency of the conventional filter is limited by the resistance and the capacitance of the semiconductor device, thus conventional filter quality suffers.

### SUMMARY OF THE INVENTION

The object of the present invention is thus to provide a low-pass filter circuit using a resistor network structure significantly with large equivalent resistance without occupying a large IC area.

To achieve the above-mentioned object, the filter circuit of the present invention provides a transconductance device for outputting a current signal according to an input voltage and a feedback voltage; a transresistance device coupled to the transconductance device for outputting a output voltage according to the current signal; and a feedback device coupled between the transconductance device and the transresistance device for outputting the feedback voltage according to the output voltage. The transresistance device is coupled to the transconductance device via a resistor network comprising a plurality of stages connected serially, wherein each stage of the resistor network comprises: an input node; an output node; a first resistor coupled between the input node and the ground; and a second resistor coupled between the input node and the output node.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIG. 1 is a circuit showing the conventional low-pass filter.

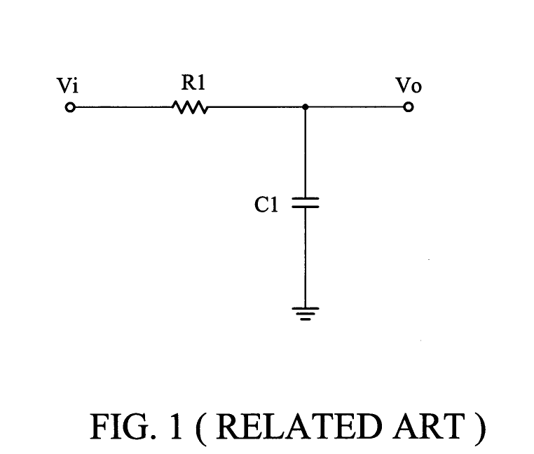

FIG. 2 is a circuit of a resistor ladder comprising five stages.

FIG. 3 is a circuit showing the low-pass filter circuit according to one embodiment of the present invention.

### DETAILED DESCRIPTION OF THE INVENTION

The low-pass filter circuit according to one embodiment of the present invention implements an additional negative feedback path and a resistor network to decrease the required resistance of the filter circuit. The circuit structure of the resistor network is described in the following.

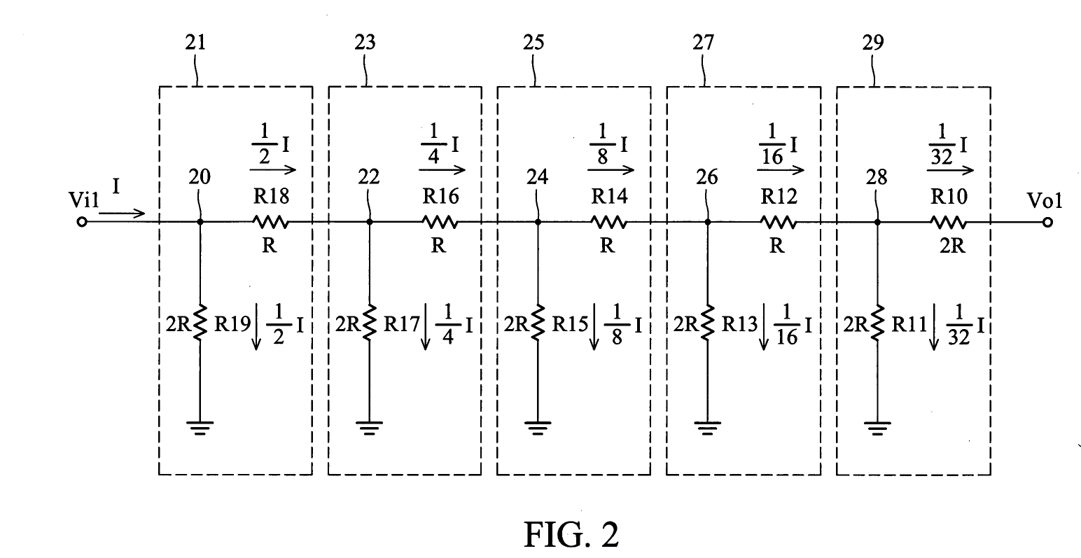

FIG. 2 is a circuit of a resistor network comprising five stages. The resistances of the resistors can be set to any combination. Here, the resistance of the resistors R10, R11, R13, R15, R17 and R19 is set as the twice that of the resistors R12, R14, R16 and R18. The equivalent circuit of the resistor network is the resistance of the parallel connection of the resistors R10 and R11 is 1R, is then connected in series to the resistor R12, thus the equivalent resistance is 2R. Next, the equivalent resistor is connected in parallel to the R13 and so on. Thus, the resistance of each current path at the nodes 20, 22, 24, 26 and 28 is 2R. Therefore, when the current I is input to the input terminal Vi1, the current value of the current is halved when passing through the nodes 20, 22, 24, 26 and 28. FIG. 2 also shows the value of the current on each resistor. Because the circuit structure is a resistor network having five stages, the value of the current output from the output terminal Vol is I/2⁵. In addition, the output current decreases when the stage number of the resistor ladder increases.

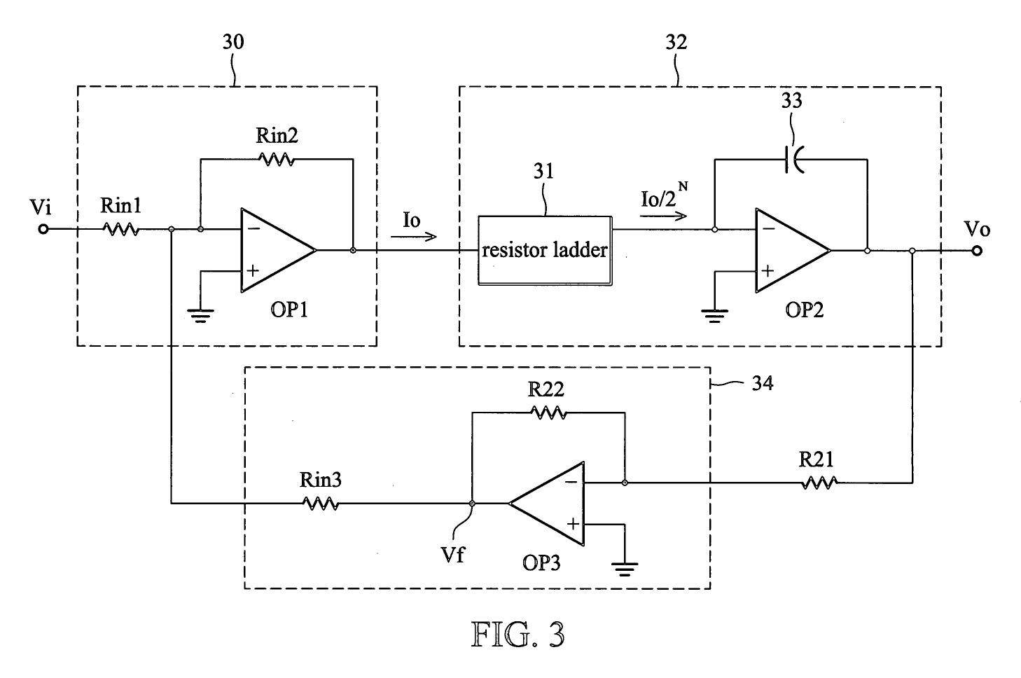

FIG. 3 is a circuit showing the low-pass filter circuit according to one embodiment of the present invention. The low-pass filter circuit according the embodiment of the present invention implements an additional negative feedback path and a resistor network to obtain a filter with excellent low-pass quality.

The low-pass filter circuit according to the embodiment of the present invention comprises an adder 30 and an integrator 32. In addition, a feedback circuit 34 is connected between the input terminal of the adder 30 and the output terminal of the integrator 32.

The input terminal of the adder 30 receives input voltage Vi and a feedback voltage Vf, and outputs an output current Io according to the sum of the voltage level of the input voltage Vi and the feedback voltage Vf. The adder 30 comprises an operational amplifier OP1 having a grounded non-converting input terminal, a converting input terminal and an output terminal to output the output current Io. The resistor Rin2 is connected between the output terminal and the converting input terminal of the operational amplifier OP1. Here, the value of the output current Io is the sum of the current passing through the resistors Rin1 and Rin3.

The integrator 32 is coupled to the adder 30 to output an output voltage Vo. The integrator 32 comprises a resistive network 31, a capacitor 33 and an operational amplifier OP2 having a grounded non-converting input terminal, a converting input terminal and an output terminal. Here, the capacitor 33 is coupled between the output terminal and the converting input terminal of the operational amplifier OP2.

In addition, the resistive network 31 is composed of a plurality of stages, wherein the circuit of the resistor network has been shown in FIG. 2. Each stage of the resistor ladder (21, 23, 25, 27, and 29) includes a first current path and a second current path, which are connected to the node of the stage. The first-stage resistor network 21 is connected to the adder 30, and the last-stage resistor network 29 is connected to the converting input terminal of the operational amplifier OP2. The first current path of each stage is connected to the node of the next-stage resistor ladder, and the second current paths of the resistor network are all grounded.

The feedback circuit 34 is coupled between the output terminal Vo and the converting input terminal of the operational amplifier OP1 to transfer the output signal of the integrator circuit 32 to the feedback signal Vf. Here, the feedback signal Vf is inverted to the output signal of the integrator circuit 32. The feedback circuit 34 comprises an operational amplifier OP3 having a grounded non-converting input terminal, a converting input terminal coupled to the output terminal Vo and a output terminal coupled to the converting input terminal of the operational amplifier OP1 to output the feedback signal Vf. The resistor R11 is coupled between the output terminal of the operational amplifier OP2 and the converting input terminal of the operational amplifier OP3, and the resistor R12 is coupled between the output terminal and the converting input terminal of the operational amplifier OP3.

If the resistance of the resistors R21 and R22 are the same, the operational amplifier OP3 generates the reverse voltage of the output voltage Vo. If, however, the resistance of resistors R21 and R22 can be adjusted according to feedback to achieve an appropriate feedback value. The appropriate feedback value is added to the input voltage Vi, combining the resistor network and the integrator 32, thus a low-pass filter is obtained, which has a cut-off frequency 1/(Req×C1). Here, Req represents the equivalent resistance of the resistor network. In addition, the integrator 32 according to the embodiment of the present invention implements the resistor network as the resistive load 31, so the equivalent resistance Req of the resistive load 31 is R×2^{N}. Using a 16-stage resistor network as an example, the unit resistance is 0.024 Meg. In addition, the total resistance is only 1.176 Meg. Compared with the conventional low-pass filter circuit, the low-pass filter circuit of the present invention achieves the same cut-off frequency by using 1/1353 resistance of the conventional low-pass filter circuit.

In addition, the feedback circuit 34 and the adder 30 can be replaced with a subtractor. In the present invention, the proportional of the resistance on the first current path and the second current path isn't limited on 1:2, actually, can be any other value, for example, 1:3 or 3:2. In other words, a larger resistance is obtained by using the resistor network with a plurality of stages.

Accordingly, the high equivalent resistance of the resistor network decreases the required resistance of the low-pass filter. Thus, higher resistance is achieved in the semiconductor device. Therefore, an ideal low cut-off frequency of the low-pass filter according to the embodiment of the present invention is achieved and the filtering effect is improved.

It should be noted that the resistor network disclosed in the embodiments of the present invention is suitable to be implemented inside of the IC device such that the resistor network can be with large resistance without occupying a large area. In addition, each resistor of the resistor network can be implemented by the MOS transistor. The resistance of each resistor and/or the number of the stages of the resistor network can be determined through controlling the gate voltage of the corresponding MOS transistors.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A filter circuit, comprising:
a transconductance device for outputting a current signal according to an input voltage and a feedback voltage;
a transresistance device coupled to the transconductance device for outputting a output voltage according to the current signal, wherein the transresistance device comprises:
a first capacitor;
a resistor network coupled to the capacitor and the transconductance device comprising a plurality of stages connected serially, wherein each stage of the resistor network comprises:
an input node;
an output node;
a first resistor coupled between the input node and the ground; and
a second resistor coupled between the input node and the output node;
wherein a time constant of the filter circuit is determined by the first capacitor and the resistor network; and
a feedback device coupled between the transconductance device and the transresistance device for outputting the feedback voltage according to the output voltage.

2. The filter circuit as claimed in claim 1, wherein the transconductance device comprises:
a first operational amplifier having a first non-converting input terminal coupled to a ground, a first converting input terminal and a first output terminal to output the current signal;
a first resistor coupled to the first output terminal and the first converting input terminal; and
a second resistor coupled to the first converting input terminal for receiving the input voltage.

3. The filter circuit as claimed in claim 1, wherein the transresistance device comprises:
a second operational amplifier having a second non-converting input terminal coupled to a ground, a second converting input terminal and a second output terminal to output the output voltage;
the first capacitor coupled to the second output terminal and the second converting input terminal; and
the resistor network coupled to the second converting input terminal for receiving the current signal.

4. The filter circuit as claimed in claim 3, wherein the resistance of the first resistor is two times larger than the resistance of the second resistor.

5. The amplifier circuit as claimed in claim 4, wherein the equivalent resistance of the resistor network is 2ⁿ×R, wherein the resistor network includes n stages and the resistance of the second resistor is R.

6. The amplifier circuit as claimed in claim 3, wherein each of the first resistor and the second resistor is implemented by a MOS transistor.

7. The filter circuit as claimed in claim 1, wherein the feedback device comprises:
a third operational amplifier having a third non-converting input terminal coupled to a ground, a third converting input terminal and a third output terminal to output the output voltage;
a third resistor coupled to the third output terminal and the third converting input terminal; and
a fourth resistor coupled to the third output terminal for outputting the feedback voltage.
